(19) United States
(12) Patent Application Publication
(10) Pub. No.: US 2022/0310539 A1
(43) Pub. Date: Sep. 29, 2022

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Yoshiharu TAKADA, Nonoichi Ishikawa (JP)

(21) Appl. No.: 17/470,667

(22) Filed: Sep. 9, 2021

(30) Foreign Application Priority Data
Mar. 23, 2021 (JP) 2021-048233

(51) Int. Cl. H01L 23/00; H01L 29/78; H01L 29/423

(52) U.S. Cl. CPC H01L 24/05; H01L 24/32; H01L 29/7812; H01L 29/42364; H01L 29/4916

(57) ABSTRACT

A semiconductor device includes a first semiconductor layer, a first metal layer, a bonding layer, a second metal layer, and a second semiconductor layer. The first metal layer is located on the first semiconductor layer and is in contact with the first semiconductor layer. The bonding layer is located on the first metal layer and is in contact with the first metal layer. The bonding layer is conductive. The second metal layer is located on the bonding layer and is in contact with the bonding layer. The second semiconductor layer is located on the second metal layer and is in contact with the second metal layer. The second semiconductor layer includes at least a portion of a semiconductor element.

### CROSS-REFERENCE TO RELATED APPLICATIONS

This application is based upon and claims the benefit of priority from Japanese Patent Application No. 2021-048233, filed on Mar. 23, 2021; the entire contents of which are incorporated herein by reference.

### FIELD

Embodiments relate to a semiconductor device.

### BACKGROUND

In a semiconductor device in which a metal layer and a semiconductor layer are stacked, warp may occur due to the difference between the thermal expansion coefficient of the metal and the thermal expansion coefficient of the semiconductor. For example, warp may occur in a semiconductor device manufactured as a chip due to the temperature change when using solder to mount the semiconductor device to a package substrate or the like.

### BRIEF DESCRIPTION OF THE DRAWINGS

FIG. 1 is a cross-sectional view illustrating a semiconductor device according to an embodiment;

FIG. 2 is a table illustrating materials of a portion of the semiconductor device according to the embodiment;

FIGS. 3A to 3D are cross-sectional views illustrating the method for manufacturing the semiconductor device according to the embodiment;

FIGS. 4A and 4B are cross-sectional views illustrating dicing processes;

FIG. 5 is a cross-sectional view illustrating another semiconductor device according to the embodiment;

FIG. 6 is a cross-sectional view illustrating another semiconductor device according to the embodiment; and

FIG. 7 is a cross-sectional view illustrating another semiconductor device according to the embodiment.

### DETAILED DESCRIPTION

According to one embodiment, a semiconductor device includes a first semiconductor layer, a first metal layer, a bonding layer, a second metal layer, and a second semiconductor layer. The first metal layer is located on the first semiconductor layer and is in contact with the first semiconductor layer. The bonding layer is located on the first metal layer and is in contact with the first metal layer. The bonding layer is conductive. The second metal layer is located on the bonding layer and is in contact with the bonding layer. The second semiconductor layer is located on the second metal layer and is in contact with the second metal layer. The second semiconductor layer includes at least a portion of a semiconductor element.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

In the embodiments described below, each embodiment may be implemented by inverting the p-type (an example of the second conductivity type) and the n-type (an example of the first conductivity type) of each semiconductor region.

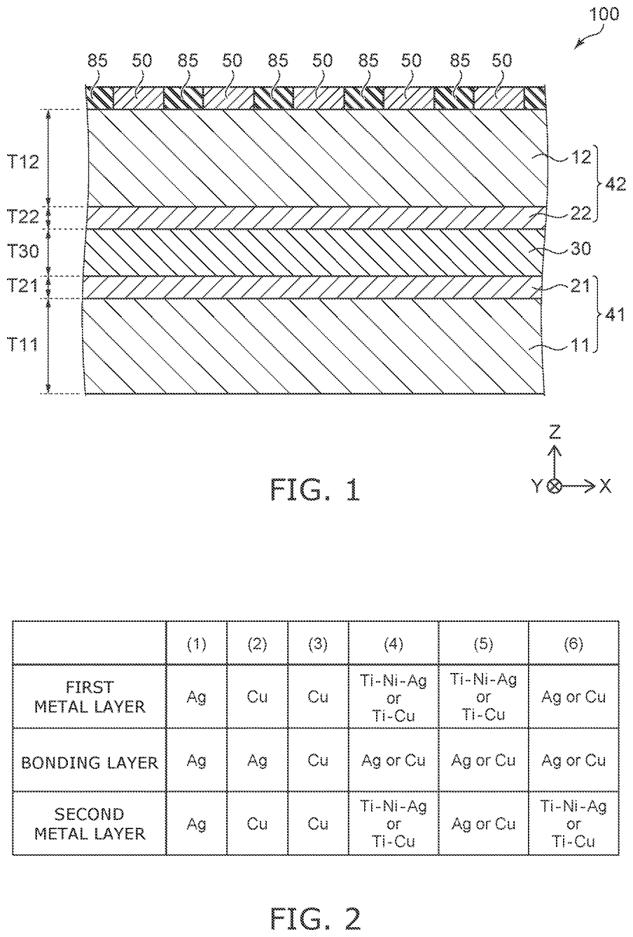

FIG. 1 is a cross-sectional view illustrating a semiconductor device according to an embodiment.

As illustrated in FIG. 1, the semiconductor device 100 according to the embodiment includes a first semiconductor layer 11, a first metal layer 21, a bonding layer 30, a second metal layer 22, and a second semiconductor layer 12.

In the description of the embodiments, a direction from the first semiconductor layer 11 toward the second semiconductor layer 12 is taken as a Z-direction; one direction perpendicular to the Z-direction is taken as an X-direction; and a direction perpendicular to the Z-direction and the X-direction is taken as a Y-direction (a third direction). In the description, the direction from the first semiconductor layer 11 toward the second semiconductor layer 12 is called “up”; and the opposite direction is called “down”. These directions are based on the relative positional relationship between the first semiconductor layer 11 and the second semiconductor layer 12, and are independent of the direction of gravity.

The first metal layer 21 is located on the first semiconductor layer 11 and contacts the first semiconductor layer 11. The bonding layer 30 is located on the first metal layer 21 and contacts the first metal layer 21. The second metal layer 22 is located on the bonding layer 30 and contacts the bonding layer 30. The second semiconductor layer 12 is located on the second metal layer 22 and contacts the second metal layer 22.

The bonding layer 30 bonds the first metal layer 21 and the second metal layer 22. The bonding layer 30 is conductive and is, for example, a metal layer. The bonding layer 30 is electrically connected with the first and second metal layers 21 and 22. In other words, the first metal layer 21 and the second metal layer 22 are electrically connected via the bonding layer 30.

At least a portion of a semiconductor element (e.g., a first element S1 and a second element S2 described below) is provided in the second semiconductor layer 12. The semiconductor element is, for example, a field effect transistor (e.g., a Metal-Oxide-Semiconductor Field Effect Transistor (MOSFET)). An electrode 50 and an insulating layer 85 of the semiconductor element are located at the upper surface of the second semiconductor layer 12. However, the semiconductor element that is provided in the second semiconductor layer 12 is not limited to a MOSFET and may be, for example, any semiconductor element such as an insulated gate bipolar transistor (IGBT), a diode, etc.

The first metal layer 21 and the first semiconductor layer 11 are stacked in a lower stacked structure 41 under the bonding layer 30; the second metal layer 22 and the second semiconductor layer 12 are stacked in an upper stacked structure 42 on the bonding layer 30; for example, the lower stacked structure 41 and the upper stacked structure 42 have a symmetric structure around the bonding layer 30.

A thickness T11 (the length along the Z-direction) of the first semiconductor layer 11 is, for example, not less than 0.9 times and not more than 1.1 times a thickness T12 of the second semiconductor layer 12. For example, it is favorable for the thickness T11 to be equal to the thickness T12. For example, the thickness T11 is not less than 10 μm and not more than 50 μm, and favorably not more than 45 μm, and more favorably not more than 30 μm.

A thickness T21 of the first metal layer 21 is, for example, not less than 0.9 times and not more than 1.1 times a thickness T22 of the second metal layer 22. For example, it is favorable for the thickness T21 to be equal to the thickness T22. The thickness T21 is, for example, not less than 5 μm and not more than 10 μm.

A thickness T30 of the bonding layer 30 is, for example, greater than the thickness T21 of the first metal layer 21 and greater than the thickness T22 of the second metal layer 22. The thickness T30 is, for example, not less than 10 μm and not more than 40 μm.

The density (g/cm³) of the bonding layer 30 is less than the density (g/cm³) of the first metal layer 21 and less than the density (g/cm³) of the second metal layer 22. For example, multiple voids are dispersed in the bonding layer 30.

Materials of the semiconductor device according to the embodiment will now be described.

The first semiconductor layer 11 and the second semiconductor layer 12 include silicon. For example, the first semiconductor layer 11 and the second semiconductor layer 12 each are formed by singulating a silicon wafer. The impurity concentration of the second semiconductor layer 12 may be higher than the impurity concentration of the first semiconductor layer 11.

The first metal layer 21 and the second metal layer 22 include, for example, at least one of silver (Ag), copper (Cu), nickel (Ni), or gold (Au). For example, the first metal layer 21 and the second metal layer 22 are formed by sputtering or plating. For example, the thermal expansion coefficient (the linear expansion coefficient) of the first metal layer 21 is greater than the thermal expansion coefficients of the first and second semiconductor layers 11 and 12. For example, the thermal expansion coefficient of the second metal layer 22 is greater than the thermal expansion coefficients of the first and second semiconductor layers 11 and 12.

The bonding layer 30 includes, for example, at least one of silver or copper. For example, the thermal expansion coefficient of the bonding layer 30 is greater than the thermal expansion coefficients of the first and second semiconductor layers 11 and 12.

FIG. 2 is a table illustrating materials of a portion of the semiconductor device according to the embodiment.

(1) to (6) of FIG. 2 are examples of combinations of the materials of the first metal layer 21, the second metal layer 22, and the bonding layer 30.

In (1) illustrated in FIG. 2, the first metal layer 21, the second metal layer 22, and the bonding layer 30 are Ag. In (2), the first metal layer 21 and the second metal layer 22 are Cu, and the bonding layer 30 is Ag. In (3), the first metal layer 21, the second metal layer 22, and the bonding layer 30 are Cu. Thus, the material of the first metal layer 21 and the material of the second metal layer 22 may be the same. The material of the bonding layer 30 may be the same as or different from the material of the first or second metal layer 21 or 22.

The first metal layer 21 and the second metal layer 22 may have a stacked structure. For example, in (4) illustrated in FIG. 2, the first metal layer 21 and the second metal layer 22 each have a stacked structure of a Ti layer, a Ni layer, and a Ag layer, or a stacked structure of a Ti layer and a Cu layer. For example, the Ti layer of the first metal layer 21, the Ni layer of the first metal layer 21, the Ag layer of the first metal layer 21, the bonding layer 30 (Ag or Cu), the Ag layer of the second metal layer 22, the Ni layer of the second metal layer 22, and the Ti layer of the second metal layer 22 are stacked in this order. Or, the Ti layer of the first metal layer 21, the Cu layer of the first metal layer 21, the bonding layer 30 (Ag or Cu), the Cu layer of the second metal layer 22, and the Ti layer of the second metal layer 22 are stacked in this order.

The material of the first metal layer 21 and the material of the second metal layer 22 may not always be the same. For example, in (5) illustrated in FIG. 2, the first metal layer 21 has a stacked structure of a Ti layer, a Ni layer, and a Ag layer or a stacked structure of a Ti layer and a Cu layer; and the second metal layer 22 is Ag or Cu. For example, the Ti layer of the first metal layer 21, the Ni layer of the first metal layer 21, the Ag layer of the first metal layer 21, the bonding layer 30 (Ag or Cu), and the second metal layer 22 (Ag or Cu) are stacked in this order. Or, the Ti layer of the first metal layer 21, the Cu layer of the first metal layer 21, the bonding layer 30 (Ag or Cu), and the second metal layer 22 (Ag or Cu) are stacked in this order.

In (6), the first metal layer 21 is Ag or Cu; and the second metal layer 22 has a stacked structure of a Ti layer, a Ni layer, and a Ag layer, or a stacked structure of a Ti layer and a Cu layer. For example, the first metal layer 21 (Ag or Cu), the bonding layer 30 (Ag or Cu), the Ag layer of the second metal layer 22, the Ni layer of the second metal layer 22, and the Ti layer of the second metal layer 22 are stacked in this order. Or, the first metal layer 21 (Ag or Cu), the bonding layer 30 (Ag or Cu), the Cu layer of the second metal layer 22, and the Ti layer of the second metal layer 22 are stacked in this order.

A method for manufacturing the semiconductor device according to the embodiment will now be described.

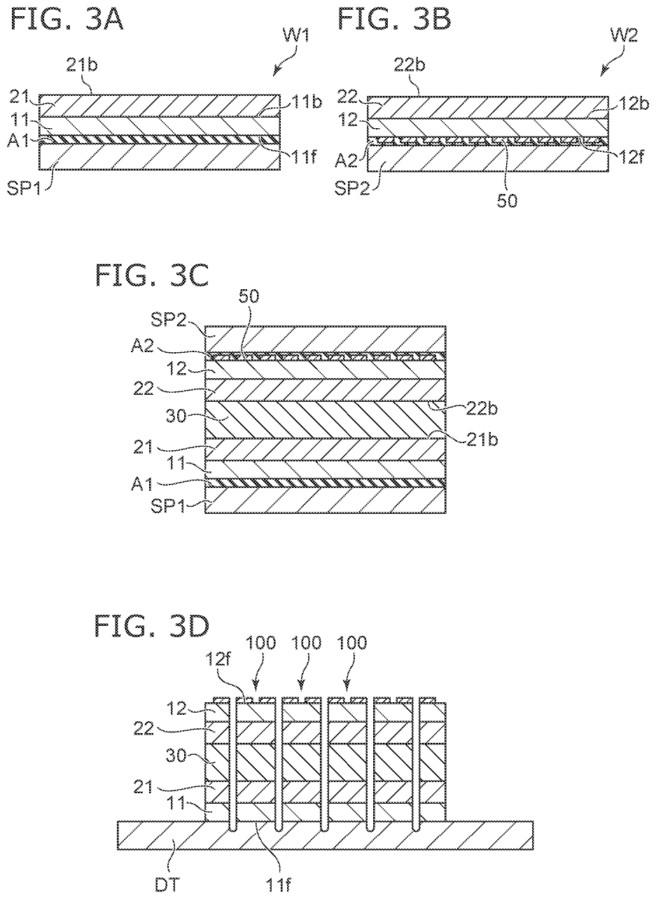

FIGS. 3A to 3D are cross-sectional views illustrating the method for manufacturing the semiconductor device according to the embodiment.

First, a first wafer W1 illustrated in FIG. 3A and a second wafer W2 illustrated in FIG. 3B are prepared.

As illustrated in FIG. 3A, the first wafer W1 includes the stacked structure of the first semiconductor layer 11 and the first metal layer 21 and is supported by a support substrate SP1. Specifically, for example, the first metal layer 21 is formed by plating on a back surface lib of a silicon substrate that is used to form the first semiconductor layer 11. For example, a glass support substrate SP1 is adhered using an adhesive A1 to a front surface 11f of the first semiconductor layer 11 at the side opposite to the back surface 11b.

As illustrated in FIG. 3B, the second wafer W2 includes the stacked structure of the second semiconductor layer 12 and the second metal layer 22 and is supported by a support substrate SP2. Specifically, for example, a semiconductor element is formed in a silicon substrate that is used to form the second semiconductor layer 12; and the second metal layer 22 is formed by plating on a back surface 12b. A surface metal (e.g., the electrode 50) is located at a front surface 12f of the second semiconductor layer 12 at the side opposite to the back surface 12b. For example, a glass support substrate SP2 is adhered to the front surface 12f by using an adhesive A2.

The first wafer W1 and the second wafer W2 are bonded as illustrated in FIG. 3C. In other words, the first metal layer 21 and the second metal layer 22 are bonded using an adhesive that is used to form the bonding layer 30. The adhesive includes, for example, a solvent and particles of a metal (e.g., silver or copper). More specifically, a conductive die attach material such as a silver paste, a silver sintering paste, a silver nanosintering material, etc., can be used.

For example, a silver nanosintering material is coated onto at least one of a back surface 21b of the first metal layer 21 (the surface at the side opposite to the first semiconductor layer 11) or a back surface 22b of the second metal layer 22 (the surface at the side opposite to the second semiconductor layer 12); the back surface 21b and the back surface 22b are caused to face each other via the adhesive; bonding is performed; subsequently, the support substrates SP1 and SP2 are detached; and the bonding layer 30 that bonds the first metal layer 21 and the second metal layer 22 is formed by heating. It should be noted that the heating may be performed before the support substrates SP1 and SP2 are detached.

As illustrated in FIG. 3D, a dicing tape DT is adhered to the front surface 11f of the first semiconductor layer 11. Then, singulation into chips is performed using a dicing blade by cutting the wafer from the front surface 12f side of the second semiconductor layer 12 toward the dicing tape DT (a dicing process). The semiconductor device 100 is manufactured thereby.

Effects according to the embodiment will now be described.

Heat is applied to the chips when solder is used to mount the chips to the substrate, etc. For example, due to the difference between the thermal expansion coefficient of the first semiconductor layer 11 and the thermal expansion coefficient of the first metal layer 21 of the lower stacked structure 41 illustrated in FIG. 1, stress is generated to warp the lower stacked structure 41 to be upwardly convex. On the other hand, due to the difference between the thermal expansion coefficient of the second semiconductor layer 12 and the thermal expansion coefficient of the second metal layer 22 of the upper stacked structure 42, stress is generated to warp the upper stacked structure 42 to be downwardly convex. According to the embodiment, the lower stacked structure 41 and the upper stacked structure 42 have oppositely-oriented warp, and are bonded by the bonding layer 30. The warp that is generated in the entire bonded wafer or chip can be suppressed thereby. For example, at least a portion of the stress that warps the lower stacked structure 41 and at least a portion of the stress that warps the upper stacked structure 42 are balanced; and the stress that acts on the entire semiconductor device can be reduced. Thus, it is possible to prevent, for example, the chip breaking.

As described above, the thickness T11 of the first semiconductor layer 11 is not less than 0.9 times and not more than 1.1 times the thickness T12 of the second semiconductor layer 12. The thickness T21 of the first metal layer 21 is not less than 0.9 times and not more than 1.1 times the thickness T22 of the second metal layer 22. The first metal layer 21 and the second metal layer 22 include the same metal material. In other words, the lower stacked structure 41 and the upper stacked structure 42 have similar structures. The warp can be further suppressed thereby. For example, the difference between the magnitude of the stress that warps the lower stacked structure 41 to be upwardly convex and the magnitude of the stress that warps the upper stacked structure 42 to be downwardly convex can be reduced.

The thickness T30 of the bonding layer 30 is greater than the thickness T21 of the first metal layer 21 and the thickness T22 of the second metal layer 22. By thinning the first metal layer 21, the warp of the first wafer W1 shown in FIG. 3A due to the first metal layer 21 can be suppressed. By thinning the second metal layer 22, the warp of the second wafer W2 shown in FIG. 3B due to the second metal layer 22 can be suppressed. By suppressing the warp of the wafer, the decrease of the manufacturing efficiency of the semiconductor device can be suppressed. For example, the difficulty when handling the wafer due to the warp can be suppressed.

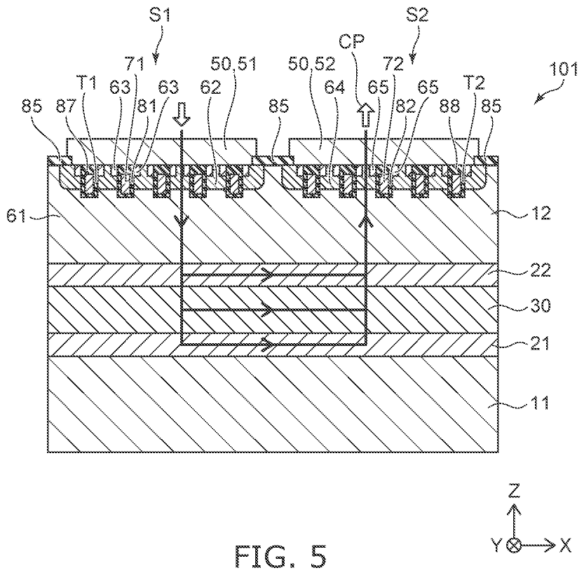

For example, as described below with reference to FIG. 5, when a stacked body of the first metal layer 21, the second metal layer 22, and the bonding layer 30 is used as an electrode (or an interconnect) of the semiconductor element, the cross-sectional area of the current path can be increased and the electrical resistance of the electrode can be reduced by setting the bonding layer 30 to be thick. The electrical characteristics of the semiconductor element can be improved thereby.

The bonding layer 30 includes the same metal material as at least one of the first metal layer 21 or the second metal layer 22. Thereby, the bonding layer 30 and at least one of the first metal layer 21 or the second metal layer 22 are electrically bonded more easily. For example, the contact resistance of the interface between the bonding layer 30 and the metal layer can be reduced.

As described above, the semiconductor element is provided in the second semiconductor layer 12. On the other hand, the semiconductor element may not be provided in the first semiconductor layer 11. The impurity concentration of the first semiconductor layer 11 may be less than the impurity concentration of the second semiconductor layer 12. Thereby, the substrate that is used as the semiconductor substrate (e.g., the silicon wafer) used to form the first semiconductor layer 11 can be less expensive than the semiconductor substrate (e.g., the silicon wafer) used to form the second semiconductor layer 12. Because the impurity concentration of the second semiconductor layer 12 is high, the electrical characteristics of the semiconductor element provided in the second semiconductor layer 12 can be improved. For example, as described below with reference to FIG. 5, the on-resistance of the transistor can be reduced.

The density of the bonding layer 30 may be less than the densities of the first and second metal layers 21 and 22. For example, such a bonding layer 30 can be formed of a silver nanosintering material, a silver paste, etc. In other words, the first metal layer 21 and the second metal layer 22 can be bonded using a simple method that uses a nanosintering material, a silver paste, etc.

The level of the density can be determined from the number and/or size of the voids included in each layer. Specifically, for example, the density of the bonding layer 30 can be considered to be lower than the density of the first metal layer 21 when the total area of voids per unit area in the cross section of the bonding layer 30 is greater than the total area of voids per unit area in the cross section of the first metal layer 21, or when voids exist in the cross section of the bonding layer 30 and do not exist in the cross section of the first metal layer 21. Similarly, for example, the density of the bonding layer 30 can be considered to be less than the density of the second metal layer 22 when the total area of voids per unit area in the cross section of the bonding layer 30 is greater than the total area of voids per unit area in the cross section of the second metal layer 22, or when voids exist in the cross section of the bonding layer 30 and do not exist in the cross section of the second metal layer 22. These cross sections can be observed using an optical microscope or a scanning electron microscope (SEM).

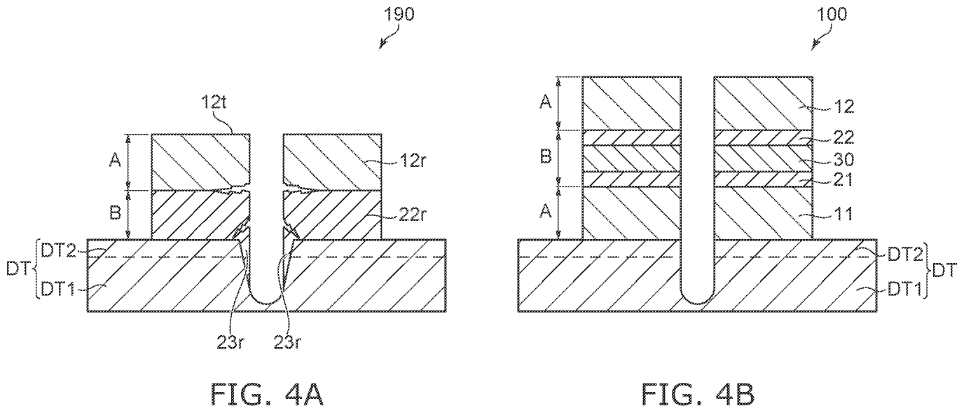

FIGS. 4A and 4B are cross-sectional views illustrating dicing processes.

FIG. 4A illustrates a dicing process of a semiconductor device 190 according to a reference example. FIG. 4B illustrates a dicing process of the semiconductor device 100 according to the embodiment.

As illustrated in FIG. 4A, the semiconductor device 190 includes a metal layer 22r and a semiconductor layer 12r. The semiconductor layer 12r is located on the metal layer 22r. The first semiconductor layer 11, the first metal layer 21, and the bonding layer 30 are not located in the semiconductor device 190. The material of the metal layer 22r and the material of the semiconductor layer 12r are respectively similar to the material of the second metal layer 22 and the material of the second semiconductor layer 12. The thickness (a thickness B) of the metal layer 22r is equal to the total thickness of the first metal layer 21, the bonding layer 30, and the second metal layer 22. The thickness (a thickness A) of the semiconductor layer 12r is equal to the thickness of the second semiconductor layer 12. The dicing tape DT includes a glue layer DT2 that is located on a base DT1. The glue layer DT2 contacts the metal layer 22r.

The semiconductor device 190 is manufactured by cutting the wafer with a dicing blade from an upper surface 12t side of the semiconductor layer 12r toward the dicing tape DT. Here, metal is ductile; therefore, when the metal layer 22r is cut on the dicing tape DT, there are cases where the metal layer 22r elongates, and burr 23r occurs. The burr 23r may cause defects of the semiconductor device. For example, there is a possibility that the burr 23r may separate from the metal layer 22r, attach to the chip surface, and cause a short defect.

Conversely, in the semiconductor device 100 according to the embodiment as illustrated in FIG. 4B, the first metal layer 21 and the second metal layer 22 are located between the first semiconductor layer 11 and the second semiconductor layer 12. The glue layer DT2 contacts the first semiconductor layer 11. In the dicing process, the first metal layer 21 and the second metal layer 22 are positioned on the first semiconductor layer 11 and do not contact the dicing tape DT. In the dicing process, the elongation of the first and second metal layers 21 and 22 can be suppressed thereby, and the burr can be suppressed.

FIG. 5 is a cross-sectional view illustrating another semiconductor device according to the embodiment.

In the semiconductor device 101 illustrated in FIG. 5, the semiconductor elements that are provided in the second semiconductor layer 12 are MOSFETs. Specifically, two MOSFETs, i.e., the first element 51 and the second element S2, are provided. Otherwise, the semiconductor device 101 is similar to the semiconductor device 100.

The second semiconductor layer 12 includes a drift region 61 (a first semiconductor region), a base region 62 (a second semiconductor region), and a source region 63 (a third semiconductor region). The semiconductor device 101 further includes a gate insulating film 81 (a first insulating film) and a gate electrode 71 (a first control electrode). A source electrode 51 (a first electrode) is located on the second semiconductor layer 12 as the electrode 50. The first element 51 is a vertical MOSFET formed of the gate insulating film 81, the gate electrode 71, the source region 63, the base region 62, and a portion of the drift region 61.

The drift region 61 is located on the second metal layer 22 and contacts the second metal layer 22. The drift region 61 is of an n-type (a first conductivity type).

The base region 62 is located selectively on the drift region 61. The base region 62 is of a p-type (a second conductivity type). The source region 63 is located selectively on the base region 62. The source region 63 is of the first conductivity type (the n⁺-type). For example, the first-conductivity-type impurity concentration in the source region 63 is higher than the first-conductivity-type impurity concentration in the drift region 61. For example, multiple source regions 63 are provided; and the multiple source regions 63 are arranged in the X-direction.

The gate electrode 71 is located on the drift region 61 with the gate insulating film 81 interposed. The gate electrode 71 faces a portion of the drift region 61, the base region 62, and a portion of the source region 63 via the gate insulating film 81. For example, multiple gate electrodes 71 and multiple gate insulating films 81 are provided. The multiple gate electrodes 71 are arranged in the X-direction; and each gate electrode 71 extends in the Y-direction.

Multiple trenches T1 are formed on the drift region 61. The multiple trenches T1 are arranged in the X-direction; and each trench T1 extends in the Y-direction. Each trench T1 passes through the base region 62 from the source region 63 and reaches the drift region 61. The gate insulating film 81 is located in each trench T1; and the gate electrode 71 is located on the gate insulating film 81. An insulating portion 87 also is located between the gate electrode 71 and the source electrode 51 in each trench T1.

The source electrode 51 is located on the source region 63 and the gate electrode 71, and is electrically connected with the source region 63. The source electrode 51 and the gate electrode 71 are electrically insulated from each other by the insulating portion 87 (a first insulating portion).

The second semiconductor layer 12 further includes a base region 64 (a fourth semiconductor region) and a source region 65 (a fifth semiconductor region). The semiconductor device 101 further includes a gate insulating film 82 (a second insulating film) and a gate electrode 72 (a second control electrode). A source electrode 52 (a second electrode) is located on the second semiconductor layer 12 as the electrode 50. The second element S2 is a vertical MOSFET formed of the gate insulating film 82, the gate electrode 72, the source region 65, the base region 64, and a portion of the drift region 61.

The base region 64 is located selectively on the drift region 61. The base region 64 is separated from the base region 62 in the X-direction. The base region 64 is of the p-type (the second conductivity type). The source region 65 is located selectively on the base region 64. The source region 65 is of the first conductivity type (the n⁺-type). For example, the first-conductivity-type impurity concentration in the source region 65 is higher than the first-conductivity-type impurity concentration in the drift region 61. For example, multiple source regions 65 are provided; and the multiple source regions 65 are arranged in the X-direction.

The gate electrode 72 is located on the drift region 61 with the gate insulating film 82 interposed. The gate electrode 72 faces a portion of the drift region 61, the base region 64, and a portion of the source region 65 via the gate insulating film 82. For example, multiple gate electrodes 72 and multiple gate insulating films 82 are provided. The multiple gate electrodes 72 are arranged in the X-direction; and each gate electrode 72 extends in the Y-direction.

Multiple trenches T2 are formed on the drift region 61. The multiple trenches T2 are arranged in the X-direction; and each trench T2 extends in the Y-direction. Each trench T2 passes through the base region 64 from the source region 65 and reaches the drift region 61. The gate insulating film 82 is located in each trench T1; and the gate electrode 72 is located on the gate insulating film 82. An insulating portion 88 also is located between the gate electrode 72 and the source electrode 52 in each trench T2.

The source electrode 52 is located on the source region 65 and the gate electrode 72, and is electrically connected with the source region 65. The source electrode 52 and the gate electrode 72 are electrically insulated from each other by the insulating portion 88 (a second insulating portion). The insulating layer 85 is located between the source electrode 51 and the source electrode 52.

Operations of the semiconductor device 101 will now be described.

The semiconductor device 101 is operated by applying a gate bias to the gate electrodes 71 and 72 in a state in which a voltage is applied between the source electrode 51 and the source electrode 52. For example, when the MOSFETs are switched on by applying the gate bias to the gate electrodes 71 and 72, a current flows from the source electrode 51 toward the source electrode 52 via a path CP shown in FIG. 5.

In other words, the current that flows in the vertical direction from the source electrode 51 toward the drift region 61 flows in the vertical direction from the drift region 61 toward the source electrode 52 after flowing in the lateral direction through at least one of the second metal layer 22, the bonding layer 30, or the first metal layer 21. A current may flow from the source electrode 52 toward the source electrode 51 along a path in a direction opposite to that described above.

The stacked body of the first metal layer 21, the bonding layer 30, and the second metal layer 22 performs the role of a drain electrode for the first and second elements S1 and S2. In other words, the first element S1 and the second element S2 have a structure in which the drain electrode is shared.

Materials of the semiconductor device 101 will now be described.

When silicon is used as the material of the second semiconductor layer 12, arsenic, phosphorus, or antimony can be used as an n-type impurity. Boron can be used as a p-type impurity. For example, the base region 62, the source region 63, the base region 64, and the source region 65 can be formed by ion-implanting impurities into a silicon semiconductor substrate.

The gate electrode 71 and the gate electrode 72 include a conductive material such as polysilicon doped with an impurity, etc.

The source electrode 51 and the source electrode 52 include a metal such as aluminum, copper, silver, titanium, tungsten, etc.

The gate insulating film 81, the gate insulating film 82, the insulating layer 85, the insulating portion 87, and the insulating portion 88 include an insulating material such as silicon oxide, etc.

For example, the n-type impurity concentration in the drift region 61 is higher than the n-type impurity concentration in the first semiconductor layer 11. The electrical resistance in the drift region 61 can be reduced by setting the n-type impurity concentration in the drift region 61 to be high. The on-resistance of the MOSFET can be reduced thereby.

In common-drain MOSFETs, the electrical resistance in the drift region 61 can be reduced by thinning the drift region 61. Also, the electrical resistance of the drain electrode can be reduced by making the drain electrode thick because the cross-sectional area of the current path in the drain electrode is increased. The on-resistance of the MOSFETs can be reduced thereby.

When making the drain electrode thick, for example, a reference example such as the semiconductor device 190 described with reference to FIG. 4A may be considered in which the metal layer 22r is set to the desired thickness (the thickness B). However, when simply making the metal layer 22r thick, there is a risk that the warp of the wafer may increase. Also, when the thickness (the thickness A) of the semiconductor layer 12r is thin, there are cases where the strength of the wafer may decrease.

Conversely, according to the embodiment, the first metal layer 21 and the second metal layer 22 that are bonded by the conductive bonding layer 30 are used as the drain electrode. Therefore, even though the first metal layer 21 and the second metal layer 22 each are less than the desired thickness (the thickness B) of the reference example, the electrical resistance of the drain electrode can be reduced by increasing the total thickness of the first metal layer 21, the second metal layer 22, and the bonding layer 30. For example, the thicknesses of the first and second metal layers 21 and 22 each may be not more than half of the desired thickness (the thickness B) of the reference example.

Thus, according to the embodiment, the thicknesses of the first and second metal layers 21 and 22 each can be reduced while increasing the total thickness of the first and second metal layers 21 and 22; therefore, the warp of the first and second wafers W1 and W2 before bonding is easily suppressed while reducing the electrical resistance of the drain electrode. For example, the decrease of the strength and/or the decrease of the manufacturing efficiency due to the warp of the wafer can be suppressed.

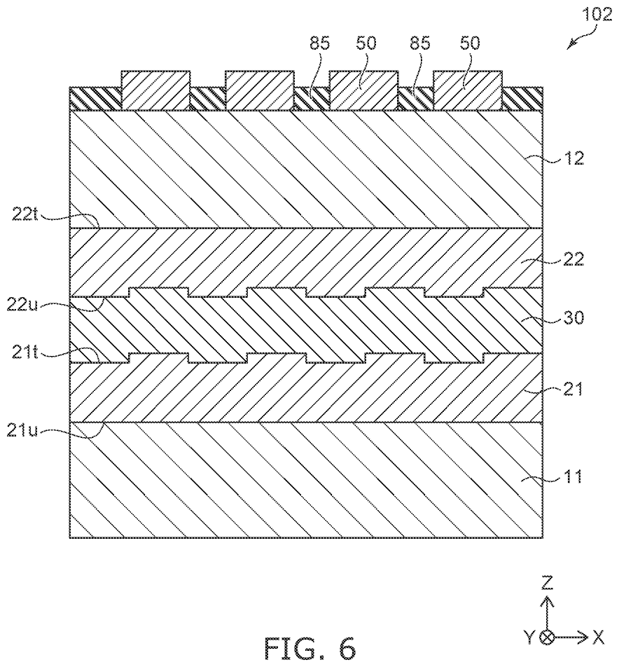

FIG. 6 is a cross-sectional view illustrating another semiconductor device according to the embodiment.

In the semiconductor device 102 illustrated in FIG. 6, an unevenness is provided in the first metal layer 21, the second metal layer 22, and the bonding layer 30. Specifically, the first metal layer 21 includes a lower surface 21u that contacts the first semiconductor layer 11, and an upper surface 21t that contacts the bonding layer 30. In the semiconductor device 102, an unevenness is provided in the upper surface 21t. An unevenness may not be provided in the lower surface 21u. The second metal layer 22 includes a lower surface 22u that contacts the bonding layer 30, and an upper surface 22t that contacts the second semiconductor layer 12. In the semiconductor device 102, an unevenness is provided in the lower surface 22u. An unevenness may not be provided in the upper surface 22t. Otherwise, the semiconductor device 102 is similar to the semiconductor device 100.

For example, the maximum height of the unevenness in the upper surface 21t of the first metal layer 21 is greater than the maximum height of the unevenness in the lower surface 21u of the first metal layer 21. For example, the maximum height of the unevenness in the lower surface 22u of the second metal layer 22 is greater than the maximum height of the unevenness in the upper surface 22t of the second metal layer 22. The maximum height of the unevenness is the maximum value of the length along the Z-direction between the hill peak and the dale bottom of the unevenness when a cross section parallel to the Z-direction is observed.

By providing the unevenness in the upper surface 21t of the first metal layer 21 that contacts the bonding layer 30, the contact area between the bonding layer 30 and the first metal layer 21 can be increased. The electrical resistance at the interface between the bonding layer 30 and the first metal layer 21 can be reduced thereby.

Similarly, by providing the unevenness in the lower surface 22u of the second metal layer 22 that contacts the bonding layer 30, the contact area between the bonding layer 30 and the second metal layer 22 can be increased. The electrical resistance at the interface between the bonding layer 30 and the second metal layer 22 can be reduced thereby.

Although rectangular unevennesses are provided in the first metal layer 21, the second metal layer 22, and the bonding layer 30 in FIG. 6, the shape of the unevenness is not limited thereto; similar effects can be obtained using a shape that has a step that is wedge-shaped, semicircular, etc.; and the period of the steps may not be uniform between the lower surface 22u and the upper surface 21t.

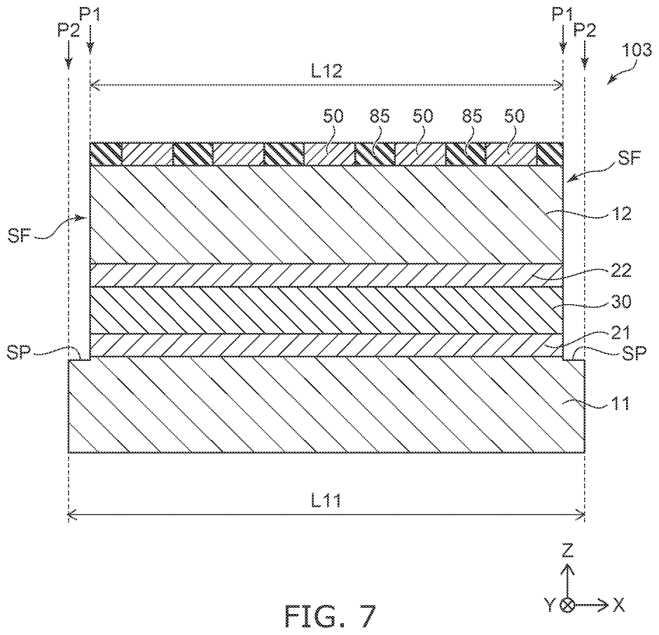

FIG. 7 is a cross-sectional view illustrating another semiconductor device according to the embodiment.

In the semiconductor device 103 as illustrated in FIG. 7, the width (a length L11 along the X-direction) of the first semiconductor layer 11 and the width (a length L12 along the X-direction) of the second semiconductor layer 12 are different. The length L11 is greater than the length L12. In other words, a shelf portion SP (a step portion) is provided in a side surface SF of the semiconductor device 103. Otherwise, the semiconductor device 103 is similar to the semiconductor device 100.

Such a semiconductor device 103 is manufactured by using a step cut in the dicing process. In other words, for example, the dicing process includes a first cutting process and a second cutting process. The first cutting process cuts the second semiconductor layer 12, the second metal layer 22, the bonding layer 30, and the first metal layer 21 with a first blade. The position of the cutting surface of the second semiconductor layer 12, the second metal layer 22, the bonding layer 30, and the first metal layer 21 at this time is taken as a cutting position P1. For example, the first cutting process ends when the first blade reaches the first semiconductor layer 11. Therefore, in the first cutting process, a portion of the upper surface of the first semiconductor layer 11 is cut. The second cutting process cuts the first semiconductor layer 11 after the first cutting process with a second blade that is thinner than the first blade. The position of the cutting surface of the first semiconductor layer 11 at this time is taken as a cutting position P2. The shelf portion SP corresponds to the difference between the cutting position P1 of the first cutting process and the cutting position P2 of the second cutting process.

Thus, the dicing of the semiconductor device according to the embodiment may be divided into multiple dicing. The wafer can be easily diced thereby, even when the semiconductor device is made thick by using the first semiconductor layer 11, the first metal layer 21, the bonding layer 30, etc. Also, different blades can be used according to the cutting objects; therefore, the accuracy of the dicing can be increased, and the wear of the blades can be suppressed.

According to embodiments, a semiconductor device can be provided in which the warp can be suppressed.

In each of the embodiments described above, the relative levels of the impurity concentrations between the semiconductor regions can be confirmed using, for example, SCM (scanning capacitance microscope). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured by, for example, SIMS (semiconductor ion mass spectrometry).

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first semiconductor layer;
a first metal layer located on the first semiconductor layer in contact with the first semiconductor layer;
a bonding layer located on the first metal layer in contact with the first metal layer, the bonding layer being conductive;
a second metal layer located on the bonding layer in contact with the bonding layer; and
a second semiconductor layer located on the second metal layer in contact with the second metal layer, the second semiconductor layer including at least a portion of a semiconductor element.

2. The device according to claim 1, wherein
a density of the bonding layer is lower than a density of the first metal layer.

3. The device according to claim 1, wherein
the bonding layer includes first voids, and the first metal layer includes second voids, a total area of first voids per unit area in a cross section of the bonding layer being greater than a total area of second voids per unit area in a cross section of the first metal layer.

4. The device according to claim 1, wherein
an impurity concentration of the second semiconductor layer is higher than an impurity concentration of the first semiconductor layer.

5. The device according to claim 1, wherein
a thickness of the first semiconductor layer is not less than 0.9 times and not more than 1.1 times a thickness of the second semiconductor layer.

6. The device according to claim 1, wherein
a thickness of the first metal layer is not less than 0.9 times and not more than 1.1 times a thickness of the second metal layer.

7. The device according to claim 1, wherein
the first metal layer and the second metal layer include a same metal material.

8. The device according to claim 1, wherein
the bonding layer includes a same metal material as at least one of the first metal layer or the second metal layer.

9. The device according to claim 1, wherein
the bonding layer is thicker than the first and second metal layers.

10. The device according to claim 1, further comprising:
a first control electrode, a second control electrode, a first electrode, and a second electrode,
the second semiconductor layer including
a first semiconductor region located on the second metal layer, the first semiconductor region being of a first conductivity type,
a second semiconductor region located on the first semiconductor region, the second semiconductor region being of a second conductivity type,
a third semiconductor region located on the second semiconductor region, the third semiconductor region being of the first conductivity type,
a fourth semiconductor region located on the first semiconductor region, the fourth semiconductor region being separated from the second semiconductor region in a direction perpendicular to a direction from the first semiconductor layer toward the second semiconductor layer, the fourth semiconductor region being of the second conductivity type, and
a fifth semiconductor region located on the fourth semiconductor region, the fifth semiconductor region being of the first conductivity type,
the first control electrode facing the second semiconductor region via a first insulating film,
the first electrode being located on the third semiconductor region and the first control electrode, being electrically connected with the third semiconductor region, and being insulated from the first control electrode by a first insulating portion,
the second control electrode facing the fourth semiconductor region via a second insulating film,
the second electrode being located on the fifth semiconductor region and the second control electrode, being electrically connected with the fifth semiconductor region, and being insulated from the second control electrode by a second insulating portion.
